(19) United States
(12) Patent Application Publication
(10) Pub. No.: US 2025/0013002 A1
(43) Pub. Date: Jan. 9, 2025

(54) CAMERAS FOR SMALL FORM FACTOR DEVICES

(71) Applicant: Meta Platforms Technologies, LLC, Menlo Park, CA (US)

(72) Inventors: Gue Hyung Kwon, San Jose, CA (US); Yi Zhou, San Jose, CA (US); Yizhi Xiong, Foster City, CA (US); Ying Zhou, Cupertino, CA (US)

(21) Appl. No.: 17/967,870

(22) Filed: Oct. 17, 2022

Related U.S. Application Data
(60) Provisional application No. 63/274,840, filed on Nov. 2, 2021.
(60) Provisional application No. 63/283,811, filed on Nov. 29, 2021.
(60) Provisional application No. 63/286,302, filed on Dec. 6, 2021.

(51) Int. Cl. G02B 7/02; G03B 30/00; H04N 5/225; H05K 1/02; H05K 1/18

(52) U.S. Cl. CPC G02B 7/028; G03B 30/00; H04N 23/57; H05K 1/0271; H05K 1/181; G02B 5/208; G02B 7/006

(57) ABSTRACT

Embodiments of the present disclosure relate to an electronic module that is structured to be incorporated into a small form factor electronic device. The electronic module includes a substrate, an active component and a passive component. The substrate includes a first surface and a second surface that is opposite the first surface. The second surface of the substrate includes a recessed area that extends through a portion of the substrate towards the first surface of the substrate. The active component is placed on the first surface of the substrate and the passive component is located in the recessed area of the second surface of the substrate.

### CROSS REFERENCE TO RELATED APPLICATIONS

This application claims priority and benefit to U.S. Provisional Patent Application Ser. No. 63/274,840, filed Nov. 2, 2021, U.S. Provisional Patent Application Ser. No. 63/283,811, filed Nov. 29, 2021, and U.S. Provisional Patent Application Ser. No. 63/286,302, filed Dec. 6, 2021, each of which is hereby incorporated by reference in its entirety.

### FIELD OF TECHNOLOGY

The present disclosure relates generally to electronic devices, and specifically relates to reducing electronic device dimensions with a recessed substrate.

### BACKGROUND

There are increasing demands to manufacture electronic modules or devices that have reduced dimensions to feed to small form factors. Conventional electronic modules include components that are mounted on a substrate. For example, in a camera device, the positioning of these components on the substrate is adjacent to the image sensor which can increase one or more dimensions of the camera device. This may be applicable for cameras with large form factors, but for cameras with small form factors (e.g., those integrated into wearable devices), increases in device dimension can be problematic.

Electronic modules may also include elements that may be affected by thermal changes. Thermal changes may be caused by the ambient environment, the local environment, and the heat generated by active components of the electronic modules. The ambient temperature is raised by system components included in the electronic modules. Raised system ambient temperature effects performance of the electronic modules.

### SUMMARY

Embodiments of the present disclosure further relate to an electronic module that is structured to be incorporated into a small form factor electronic device. The electronic module includes a substrate, an active component, and a passive component. The substrate includes a first surface and a second surface that is opposite the first surface. The second surface of the substrate includes a recessed area that extends through a portion of the substrate towards the first surface of the substrate. The active component is placed on the first surface of the substrate and the passive component is located in the recessed area of the second surface of the substrate. The active component may be an image sensor configured to capture an image and the passive component is one of a resistor, a capacitor, and an inductor. The electronic module may be incorporated into a camera device, which may be part of a wristband system, e.g., a smartwatch or some other electronic wearable device.

In some embodiments, the electronic module may further include a lens assembly coupled with the image sensor, which is configured to focus light from a local area to the image sensor of the electronic module. The lens assembly may include a lens, a lens barrel, and a lens holder both configured to hold the lens, an infrared cut filter (IRCF) configured to reduce infrared light incident on the image sensor; and an IRCF holder configured to hold the IRCF. At least a portion of the lens barrel, the lens holder and the IRCF holder are coated with a thermal material. The thermal material may be a thermal insulating material coated on outer surfaces of the lens barrel, lens holder and IRCF holder and configured to at least reduce heat conduction and/or a thermal conductive material coated on inner surfaces of the lens barrel, lens holder and IRCF holder and configured to increase heat dissipation.

Embodiments of the present disclosure further relate to an electronic device comprising an electronic module with reduced dimensions. The electronic module includes a substrate, an active component and a passive component. The substrate includes a first surface and a second surface that is opposite the first surface. The second surface of the substrate includes a recessed area that extends through a portion of the substrate towards the first surface of the substrate. The active component is placed on the first surface of the substrate and the passive component is located in the recessed area of the second surface of the substrate.

### BRIEF DESCRIPTION OF THE DRAWINGS

FIG. 1A is a plan view of an example wristband system, in accordance with one or more embodiments.

FIG. 1B is a side view of the example wristband system of FIG. 1A, in accordance with one or more embodiments.

FIG. 2A is a perspective view of an example wristband system, in accordance with one or more embodiments.

FIG. 2B is a side view of another example wristband system, in accordance with one or more embodiments.

FIG. 2C is a perspective view of another example wristband system, in accordance with one or more embodiments.

FIGS. 3A-3C illustrate exemplary surface views of an electronic module, in accordance with one or more embodiments.

FIG. 4 illustrates a cross sectional view of an electronic module along line A-A′ of FIG. 3C, in accordance with one or more embodiments.

FIGS. 5A-5C respectively illustrate exemplary views of a lens barrel, a lens holder, and an infrared cut filter (IRCF) holder, in accordance with one or more embodiments.

The figures depict various embodiments for purposes of illustration only. One skilled in the art will readily recognize from the following discussion that alternative embodiments of the structures and methods illustrated herein may be employed without departing from the principles described herein.

### DETAILED DESCRIPTION

Wearable devices may be configured to be worn on a user's body part, such as a user's wrist or arm. Such wearable devices may be configured to perform various functions. A wristband system may be an electronic device worn on a user's wrist that performs functions such as delivering content to the user, executing social media applications, executing artificial-reality applications, capturing images, messaging, web browsing, sensing ambient conditions, interfacing with head-mounted displays, monitoring the health status associated with the user, etc. However, since wearable devices are typically worn on a body part of a user, a wristband system may present an encumbrance to the user, such as when the user is sleeping or engaged in a sporting activity.

Wearable devices may be small form factor electronic devices. Examples of wearable devices include a wristband, a smartwatch or a head-mount display (HMD). A camera device and other components (e.g., haptic devices, speakers, etc.) may be incorporated into a small form factor electronic device, however, the small form factor provides limited space for the camera device. In a conventional camera structure, passive components and active components are placed on the same side of the surface of a circuit board (PCB). The positioning of these components may increase dimensions (e.g., an X and/or Y dimension) of the camera structure, thus limiting the camera's incorporation into a small form factor device.

Further, components inside a camera may be affected by thermal changes. Raised system ambient temperature may affect camera performance directly. In the optical lens assembly, thermal change may affect the refractive indices of the lens material, as well as optical thickness, and hence the curvature and lens profile of all the optical lens elements. It may also change the thickness of the opto-mechanical parts in the lens assembly including, but not limited to the spacer, soma, lens barrel, lens holder and lens cap if there is any. In the electronic module assembly, epoxy that is used to hold the lens with sensor, and the sensor base may also be also affected by thermal effect. The sensor base holder that is used to hold the IRCF (IR cut-filters) will also change the thickness by thermal heat. Thereby all these factors cause the focus shift and the final image becomes blurry at elevated temperature. Moreover, these effects are magnified in cameras with small form factors, and the conventional thermal management approaches may not be sufficient in a small form factor device.

Embodiments of the present disclosure may include an electronic module that reduces dimensions (e.g., an X and/or Y dimension) of the electronic module by placing some or all of the passive components on a side of a printed circuit board (PCB) that is opposite of a side of the PCB where an active component is placed. In order to reduce an increase in height or thickness (Z dimension) due to placing the passive components and the active component on opposite sides of the PCB, the electronic module may further include local recesses in the PCB in which the passive components are placed into.

Additionally, in some embodiments where the electronic module is a camera module, the lens barrel, the lens holder and the IRCF holder are coated with a thermal material. The thermal material may be a thermal insulating material coated on outer surfaces of the lens barrel, lens holder and IRCF holder and configured to at least reduce heat conduction; and/or a thermal conductive material coated on inner surfaces of the lens barrel, lens holder and IRCF holder and configured to increase heat dissipation.

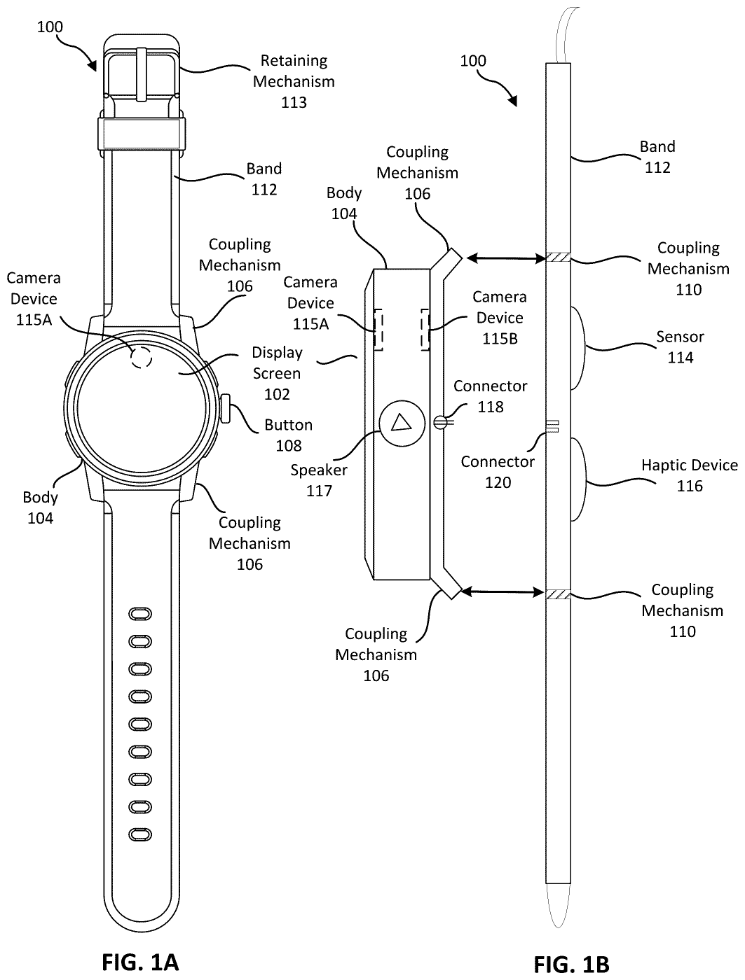

FIG. 1A illustrates an example wristband system 100 that includes a watch body 104 coupled to a watch band 112. Watch body 104 and watch band 112 may have any size and/or shape that is configured to allow a user to wear wristband system 100 on a body part (e.g., a wrist). Wristband system 100 may include a retaining mechanism 113 (e.g., a buckle) for securing watch band 112 to the user's wrist. Wristband system 100 may also include a coupling mechanism 106, 110 for detachably coupling watch body 104 to watch band 112. Wristband system 100 may perform various functions associated with the user. The functions may be executed independently in watch body 104, independently in watch band 112, and/or in communication between watch body 104 and watch band 112. Watch band 112 may be configured to operate independently (e.g., execute functions independently) from watch body 104. Additionally or alternatively, watch body 104 may be configured to operate independently (e.g., execute functions independently) from watch band 112. Watch band 112 and/or watch body 104 may each include the independent resources required to independently execute functions. For example, watch band 112 and/or watch body 104 may each include a power source (e.g., a battery), a memory, data storage, a processor (e.g., a CPU), communications, a light source (e.g., at least one infrared LED for tracking watch body 104 and/or watch band 112 in space with an external sensor), and/or input/output devices.

Functions that may be independently executed by watch body 104, by watch band 112, or by wristband system 100 may include, without limitation, display of visual content to the user (e.g., visual content displayed on display screen 102), sensing user input (e.g., sensing a touch on button 108, sensing biometric data with sensor 114, sensing neuromuscular signals with sensor 115, etc.), messaging (e.g., text, speech, video, etc.), image capture (e.g., with a front-facing image sensor 115A and/or a rear-facing image sensor 115B), wireless communications (e.g., cellular, near field, WiFi, personal area network, etc.), location determination, financial transactions, providing haptic feedback, etc. Functions may be independently executed by watch body 104, by watch band 112, or on wristband system 100 in conjunction with an artificial-reality system.

In some examples, display screen 102 may display visual content to the user. In some examples, watch body 104 may determine an orientation of display screen 102 of watch body 104 relative to an eye gaze direction of a user and may orient content viewed on display screen 102 to the eye gaze direction of the user. The displayed visual content may be oriented to the eye gaze of the user such that the content is easily viewed by the user without user intervention. Traditional displays on wristband systems may orient the visual content in a static manner such that when a user moves or rotates the wristband system, the content may remain in the same position relative to the watch band system causing difficulty for the user to view the content.

Embodiments of the present disclosure may orient (e.g., rotate, flip, stretch, etc.) the displayed content such that the displayed content remains in substantially the same orientation relative to the eye gaze of the user (e.g., the direction in which the user is looking). The displayed visual content may also be modified based on the eye gaze of the user without user intervention. For example, in order to reduce the power consumption of wristband system 100, display screen 102 may dim the brightness of the displayed content, pause the displaying of video content, or power down display screen 102 when it is determined that the user is not looking at display screen 102. In some examples, a sensor(s) of wristband system 100 may determine an orientation of display screen 102 relative to an eye gaze direction of the user.

Embodiments of the present disclosure may measure the position, orientation, and/or motion of eyes of the user in a variety of ways, including through the use of optical-based eye-tracking techniques, ultrasound-based eye-tracking techniques, etc. For example, front-facing image sensor 115A and/or rear-facing image sensor 115B may capture images of the user's eyes and determine the eye gaze direction based on processing of the captured images. The captured images may be processed using CPU 326, a processor in communication with wristband system 100 (e.g., a processor of a head-mounted display (HMD)), or a combination thereof.

In some examples, sensors other than sensors of wristband system 100 may be used to determine the user's eye gaze direction. For example, an eye-tracking subsystem of an HMD in communication with wristband system 100 may include a variety of different sensors, such as two-dimensional (2D) or three-dimensional (3D) cameras, time-of-flight depth sensors, single-beam or sweeping laser rangefinders, 3D LiDAR sensors, that may be used to determine and track the eye gaze of the user. In this example, a processing subsystem may process data from one or more of these sensors to measure, detect, determine, and/or otherwise monitor the position, orientation, and/or motion of the user's eye(s). Display screen 102 may receive the eye tracking information from the HMD, CPU 326, microcontroller unit 352, or a combination thereof, and orient the displayed content based on the user's eye gaze direction.

In some examples, watch body 104 may be communicatively coupled to an HMD. Front-facing image sensor 115A and/or rear-facing image sensor 115B may capture wide-angle images of the area surrounding front-facing image sensor 115A and/or rear-facing image sensor 115B such as hemispherical images (e.g., at least hemispherical, substantially spherical, etc.), 180-degree images, 360-degree area images, panoramic images, ultra-wide area images, or a combination thereof. In some examples, front-facing image sensor 115A and/or rear-facing image sensor 115B may be configured to capture images having a range between 45 degrees and 360 degrees. In some examples, watch body 104 may be communicatively coupled to the HMD and the HMD may be configured to display at least a portion of a captured image (e.g., a wide-angle image). The captured images may be communicated to the HMD and at least a portion of the captured images may be displayed to the user on the HMD. The images may be captured in 2D and/or 3D and displayed to the user in 2D and/or 3D. In some examples, the captured images may be displayed to the user in conjunction with an artificial-reality application. Images captured by front-facing image sensor 115A and/or rear-facing image sensor 115B may be processed before displaying on the HMD. For example, certain features and/or objects (e.g., people, faces, devices, backgrounds, etc.) of the captured image may be subtracted, added, and/or enhanced before displaying on the HMD.

FIG. 1B illustrates an example wristband system 100 that includes a watch body 104 decoupled from a watch band 112. Watch band 112 may be donned (e.g., worn) on a body part (e.g., a wrist) of a user and may operate independently from watch body 104. For example, watch band 112 may be configured to be worn by a user and an inner surface of watch band 112 may be in contact with the user's skin. When worn by a user, sensor 114 may be in contact with the user's skin. Sensor 114 may be a biosensor that senses a user's heart rate, bioimpedance, saturated oxygen level, temperature, sweat level, muscle intentions, steps taken, or a combination thereof. Watch band 112 may include multiple sensors 114 that may be distributed on an inside surface, in an interior volume, and/or on an outside surface of watch band 112. Sensor 114 may also include a sensor that provides data about a user's environment including a user's motion (e.g., an IMU), altitude, location, orientation, gait (e.g., a pedometer), or a combination thereof. Watch band 112 may transmit the data acquired by sensor 114 to watch body 104 using a wired communication method (e.g., a Universal Asynchronous Receiver Transmitter (UART), a Universal Serial Bus (USB) transceiver, etc.) and/or a wireless communication method (e.g., near field communication, Bluetooth™, etc.). In some examples, watch body 104 may include an electrical connector 118 that mates with connector 120 of watch band 112 for wired communication and/or power transfer. In some examples, watch body 104 and watch band 112 may include wireless communication devices.

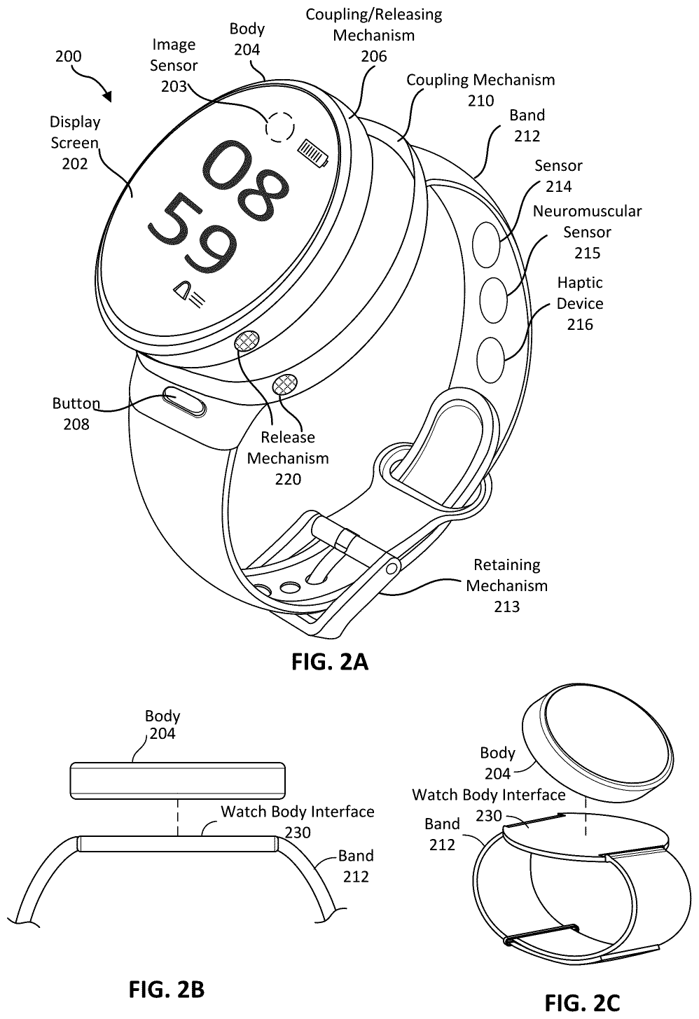

Watch band 112 and/or watch body 104 may include a haptic device 116 (e.g., a vibratory haptic actuator) that is configured to provide haptic feedback (e.g., a cutaneous and/or kinesthetic sensation) to the user's skin. Watch band 112 and/or watch body 104 may include a haptic actuator that is configured to provide haptic feedback to a user based on at least one of instructions from watch body 104 or instructions from a head-mounted display of an artificial-reality system. Sensor 114 and/or haptic device 116 may be configured to operate in conjunction with multiple applications including, without limitation, health monitoring, social media, game playing, and artificial reality. As described in detail below with reference to FIG. 2A, an electromyography sensor integrated into watch band 112 and/or watch body 104 may sense a user's muscle intention. The sensed muscle intention may be transmitted to an artificial-reality system to perform an action in an associated artificial-reality environment, such as to control a physical and/or virtual object displayed to the user. Further, the artificial-reality system may provide haptic feedback to the user in coordination with the artificial reality application via haptic device 116.

Wristband system 100 may include a coupling mechanism for detachably coupling watch body 104 to watch band 112. A user may detach watch body 104 from watch band 112 in order to reduce the encumbrance of wristband system 100 to the user. Detaching watch body 104 from watch band 112 may reduce a physical profile and/or a weight of wristband system 100. Wristband system 100 may include a watch body coupling mechanism(s) 106 and/or a watch band coupling mechanism(s) 110. Any method or coupling mechanism may be used for detachably coupling watch body 104 to watch band 112. A user may perform any type of motion to couple watch body 104 to watch band 112 and to decouple watch body 104 from watch band 112. For example, a user may twist, slide, turn, push, pull, or rotate watch body 104 relative to watch band 112, or a combination thereof, to attach watch body 104 to watch band 112 and to detach watch body 104 from watch band 112.

Watch body coupling mechanism(s) 106 and/or watch band coupling mechanism(s) 110 may include any type of mechanism that allows a user to repeat cycles of coupling and decoupling of watch body 104 relative to watch band 112. Watch body coupling mechanism(s) 106 and/or watch band coupling mechanism(s) 110 may include, without limitation, a rotation-based connector, a shear-pin coupler, a retention spring, one or more magnets, a clip, a pin shaft, a hook and loop fastener, or a combination thereof.

As illustrated in FIG. 1B, in some examples, watch body 104 may include front-facing image sensor 115A and rear-facing image sensor 115B. Front-facing image sensor 115A may be located in a front face of watch body 104 and rear-facing image sensor 115B may be located in a rear face of watch body 104. In some examples, a level of functionality of at least one of watch band 112 or watch body 104 may be modified when watch body 104 is detached from watch band 112. The level of functionality that may be modified may include the functionality of front-facing image sensor 115A and/or rear-facing image sensor 115B. By way of example, a user may use front-facing image sensor 115A to capture an image (e.g., a still image or a video) of the user, for a so-called “selfie view,” when watch body 104 is attached to or detached from watch band 112. When watch body 104 is detached from watch band 112, the user may use rear-facing image sensor 115B to capture an image (e.g., a still image or a video) of a scene or object away from the user, for a so-called “world view.” Although FIG. 1B shows a single front-facing image sensor 115A and a single rear-facing image sensor 115B, the present disclosure is not so limited. Rather, watch body 104 may include multiple front-facing image sensors 115A and/or multiple rear-facing image sensors 115B. Additionally or alternatively, watch band 112 may include at least one front-facing image sensor 115A and at least one rear-facing image sensor 115B. Of course, the orientation at which the user holds watch body 104 may alter whether the image sensors 115A and 115B are respectively used for a selfie view or a world view.

In some examples, image sensors 115A and/or 115B may be oriented to capture a first wide-angle image in a first direction. In some examples, image sensors 115A and/or 115B may be oriented to capture a second wide-angle image in a second direction opposite the first direction. The system may be configured to stitch the first wide-angle image and the second wide-angle image together to create a combined image. In some embodiments, images from front-facing image sensor 115A and from rear-facing image sensor 115B may be stitched together (e.g., with a processor) to provide a single, wide-angle image (e.g., at least hemispherical, substantially spherical, a wide-angle view, etc.), a 180-degree image, 360-degree image, a panoramic image, an ultra-wide area image, an image within the range of 45 degrees and 360 degrees, or a combination thereof, surrounding watch body 104. In some embodiments, front-facing image sensor 115A may be a wide-angle image sensor that may alone be configured to capture at least a hemispherical view surrounding watch body 104. In some examples, when watch body 104 is attached to watch band 112, rear-facing image sensor 115B or a portion thereof (e.g., certain pixels thereof) may be used to optically sense biometric data of the user.

FIG. 2A illustrates a perspective view of an example wristband system 200 that includes a watch body 204 decoupled from a watch band 212. Wristband system 200 may be structured and/or function similarly to wristband system 100 of FIGS. 1A and 1B. Watch body 204 and watch band 212 may have a substantially rectangular or circular shape and may be configured to allow a user to wear wristband system 200 on a body part (e.g., a wrist). Wristband system 200 may include a retaining mechanism 213 (e.g., a buckle, a hook and loop fastener, etc.) for securing watch band 212 to the user's wrist. Wristband system 200 may also include a coupling mechanism 206 for detachably coupling watch body 204 to watch band 212.

Wristband system 200 may perform various functions associated with the user as described above with reference to FIGS. 1A and 1B. Functions executed by wristband system 200 may include, without limitation, display of visual content to the user (e.g., visual content displayed on display screen 202), sensing user input (e.g., sensing a touch on button 208, sensing biometric data on sensor 214, sensing neuromuscular signals on neuromuscular sensor 215, etc.), messaging (e.g., text, speech, video, etc.), image capture (e.g., with a front-facing image sensor 203 and/or a rear-facing image sensor), wireless communications (e.g., cellular, near field, WiFi, personal area network, etc.), location determination, financial transactions, providing haptic feedback, alarms, notifications, biometric authentication, health monitoring, sleep monitoring, etc. These functions may be executed independently in watch body 204, independently in watch band 212, and/or in communication between watch body 204 and watch band 212. Functions may be executed on wristband system 200 in conjunction with an artificial-reality system such as the artificial-reality.

Watch band 212 may be configured to be worn by a user such that an inner surface of watch band 212 may be in contact with the user's skin. When worn by a user, sensor 214 may be in contact with the user's skin. Sensor 214 may be a biosensor that senses a user's heart rate, saturated oxygen level, temperature, sweat level, muscle intentions, or a combination thereof. Watch band 212 may include multiple sensors 214 that may be distributed on an inside and/or an outside surface of watch band 212. Additionally or alternatively, watch body 204 may include the same or different sensors than watch band 212. For example, multiple sensors may be distributed on an inside and/or an outside surface of watch body 204. Watch body 204 may include, without limitation, front-facing image sensor 115A, rear-facing image sensor 115B, a biometric sensor, an IMU, a heart rate sensor, a saturated oxygen sensor, a neuromuscular sensor(s), an altimeter sensor, a temperature sensor, a bioimpedance sensor, a pedometer sensor, an optical sensor, a touch sensor, a sweat sensor, etc. Sensor 214 may also include a sensor that provides data about a user's environment including a user's motion (e.g., an IMU), altitude, location, orientation, gait, or a combination thereof. Sensor 214 may also include a light sensor (e.g., an infrared light sensor, a visible light sensor) that is configured to track a position and/or motion of watch body 204 and/or watch band 212. Watch band 212 may transmit the data acquired by sensor 214 to watch body 204 using a wired communication method (e.g., a UART, a USB transceiver, etc.) and/or a wireless communication method (e.g., near field communication, Bluetooth™, etc.). Watch band 212 may be configured to operate (e.g., to collect data using sensor 214) independent of whether watch body 204 is coupled to or decoupled from watch band 212.

Watch band 212 and/or watch body 204 may include a haptic device 216 (e.g., a vibratory haptic actuator) that is configured to provide haptic feedback (e.g., a cutaneous and/or kinesthetic sensation, etc.) to the user's skin. Sensor 214 and/or haptic device 216 may be configured to operate in conjunction with multiple applications including, without limitation, health monitoring, social media, game playing, and artificial reality.

In some examples, watch band 212 may include a neuromuscular sensor 215 (e.g., an electromyography (EMG) sensor, a mechanomyogram (MMG) sensor, a sonomyography (SMG) sensor, etc.). Neuromuscular sensor 215 may sense a user's muscle intention. Neuromuscular sensor 215 may perform an action in an associated artificial-reality environment, such as to control the motion of a virtual device displayed to the user. Further, the artificial-reality system may provide haptic feedback to the user in coordination with the artificial-reality application via haptic device 216.

Signals from neuromuscular sensor 215 may be used to provide a user with an enhanced interaction with a physical object and/or a virtual object in an AR environment generated by an AR system. Signals from neuromuscular sensor 215 may be obtained (e.g., sensed and recorded) by one or more neuromuscular sensors 215 of watch band 212. Although FIG. 2A shows one neuromuscular sensor 215, watch band 212 may include a plurality of neuromuscular sensors 215 arranged circumferentially on an inside surface of watch band 212 such that the plurality of neuromuscular sensors 215 contact the skin of the user. Watch band 212 may include a plurality of neuromuscular sensors 215 arranged circumferentially on an inside surface of watch band 212. Neuromuscular sensor 215 may sense and record neuromuscular signals from the user as the user performs muscular activations (e.g., movements, gestures, etc.). The muscular activations performed by the user may include static gestures, such as placing the user's hand palm down on a table; dynamic gestures, such as grasping a physical or virtual object; and covert gestures that are imperceptible to another person, such as slightly tensing a joint by co-contracting opposing muscles or using sub-muscular activations. The muscular activations performed by the user may include symbolic gestures (e.g., gestures mapped to other gestures, interactions, or commands, for example, based on a gesture vocabulary that specifies the mapping of gestures to commands).

An AR system may operate in conjunction with neuromuscular sensor 215 to overlay one or more visual indicators on or near a physical and/or virtual object within the AR environment. The visual indicators may instruct the user that the physical and/or virtual object (e.g., a sporting object, a gaming object) is an object that has a set of virtual controls associated with it such that, if the user interacted with the object (e.g., by picking it up), the user could perform one or more “enhanced” or “augmented” interactions with the object. The visual indicator(s) may indicate that it is an object capable of enhanced interaction.

In another example, an indication of a set of virtual controls for the physical or virtual object, which may be activated by the user to control the object, may be overlaid on or displayed near the object in the AR environment. The user may interact with the indicator(s) of the set of virtual controls by, for example, performing a muscular activation to select one of the virtual controls. Neuromuscular sensor 215 may sense the muscular activation and in response to the interaction of the user with the indicator(s) of the set of virtual controls, information relating to an interaction with the object may be determined. For example, if the object is a virtual sword (e.g., a sword used in an AR game), the user may perform a gesture to select the virtual sword's functionality, such that, when the user picks up the virtual sword, it may be used to play a game within the AR environment.

Information relating to an interaction of the user with the physical and/or virtual object may be determined based on the neuromuscular signals obtained by the neuromuscular sensor 215 and/or information derived from the neuromuscular signals (e.g., information based on analog and/or digital processing of the neuromuscular signals). Additionally or alternatively, auxiliary signals from one or more auxiliary device(s) (e.g., front-facing image sensor 115A, rear-facing image sensor 115B, IMU 342, microphone 308, heart rate sensor 358, image sensors of the AR systems) may supplement the neuromuscular signals to determine the information relating to the interaction of the user with the physical and/or virtual object. For example, neuromuscular sensor 215 may determine how tightly the user is grasping the physical and/or virtual object, and a control signal may be sent to the AR system based on an amount of grasping force being applied to the physical object. Continuing with the example above, the object may be a virtual sword, and applying different amounts of grasping and/or swinging force to the virtual sword (e.g., using data gathered by the IMU 342) may change (e.g., enhance) the functionality of the virtual sword while interacting with a virtual game in the AR environment.

Wristband system 200 may include a coupling mechanism for detachably coupling watch body 204 to watch band 212. A user may detach watch body 204 from watch band 212 in order to reduce the encumbrance of wristband system 200 to the user. Wristband system 200 may include a watch body coupling mechanism(s) 206 and/or watch band coupling mechanism(s) 210 (e.g., a cradle, a tracker band, a support base, a clasp). Any method or coupling mechanism may be used for detachably coupling watch body 204 to watch band 212. A user may perform any type of motion to couple watch body 204 to watch band 212 and to decouple watch body 204 from watch band 212. For example, a user may twist, slide, turn, push, pull, or rotate watch body 204 relative to watch band 212, or a combination thereof, to attach watch body 204 to watch band 212 and to detach watch body 204 from watch band 212.

As shown in the example of FIG. 2A, watch band coupling mechanism 210 may include a type of frame or shell that allows watch body coupling mechanism 206 to be retained within watch band coupling mechanism 210. Watch body 204 may be detachably coupled to watch band 212 through a friction fit, magnetic coupling, a rotation-based connector, a shear-pin coupler, a retention spring, one or more magnets, a clip, a pin shaft, a hook and loop fastener, or a combination thereof. In some examples, watch body 204 may be decoupled from watch band 212 by actuation of release mechanism 220. Release mechanism 220 may include, without limitation, a button, a knob, a plunger, a handle, a lever, a fastener, a clasp, a dial, a latch, or a combination thereof.

Wristband system 200 may include a single release mechanism 220 or multiple release mechanisms 220 (e.g., two release mechanisms 220 positioned on opposing sides of wristband system 200). As shown in FIG. 2A, release mechanism 220 may be positioned on watch body 204 and/or watch band coupling mechanism 210. Although FIG. 2A shows release mechanism 220 positioned at a corner of watch body 204 and at a corner of watch band coupling mechanism 210, release mechanism 220 may be positioned anywhere on watch body 204 and/or watch band coupling mechanism 210 that is convenient for a user of wristband system 200 to actuate. A user of wristband system 200 may actuate release mechanism 220 by pushing, turning, lifting, depressing, shifting, or performing other actions on release mechanism 220. Actuation of release mechanism 220 may release (e.g., decouple) watch body 204 from watch band coupling mechanism 210 and watch band 212 allowing the user to use watch body 204 independently from watch band 212. For example, decoupling watch body 204 from watch band 212 may allow the user to capture images using rear-facing image sensor 115B.

FIG. 2B is a side view and FIG. 2C is a perspective view of another example wristband system. The wristband systems of FIGS. 2B and 2C may include a watch body interface 230. Watch body 204 may be detachably coupled to watch body interface 230. Watch body 204 may be detachably coupled to watch body interface 230. Watch body 204 may be detachably coupled to watch body interface 230 through a friction fit, magnetic coupling, a rotation-based connector, a shear-pin coupler, a retention spring, one or more magnets, a clip, a pin shaft, a hook and loop fastener, or a combination thereof.

In some examples, watch body 204 may be decoupled from watch body interface 230 by actuation of a release mechanism. The release mechanism may include, without limitation, a button, a knob, a plunger, a handle, a lever, a fastener, a clasp, a dial, a latch, or a combination thereof. In some examples, the wristband system functions may be executed independently in watch body 204, independently in watch body interface 230, and/or in communication between watch body 204 and watch body interface 230. Watch body interface 230 may be configured to operate independently (e.g., execute functions independently) from watch body 204. Additionally or alternatively, watch body 204 may be configured to operate independently (e.g., execute functions independently) from watch body interface 230. Watch body interface 230 and/or watch body 204 may each include the independent resources required to independently execute functions. For example, watch body interface 230 and/or watch body 204 may each include a power source (e.g., a battery), a memory, data storage, a processor (e.g., a CPU), communications, a light source, and/or input/output devices.

In this example, watch body interface 230 may include all of the electronic components of watch band 212. In additional examples, one or more electronic components may be housed in watch body interface 230 and one or more other electronic components may be housed in portions of watch band 212 away from watch body interface 230.

In some embodiments, the wristband system 100 may include an image sensor, for example, a camera. A camera device may be incorporated into a small form factor electronic device, such as an electronic wearable device, including a smartwatch or a head-mount display (HMD). A current (i.e., conventional) camera structure includes passive components and active components on the same side of the surface of a circuit board (PCB). The passive components may include resisters, capacitors, inductors, memory device, etc.; and the active component may be an image sensor. The PCB may include glass-fiber PCB, organic PCB, ceramic PCB, flexible printed circuit (FPC) PCB, etc. The positioning of these components may increase an x and/or y dimension of the camera structure, thus limiting the camera's incorporation into a small form factor device.

### Electronic Module Structure

An electronic module is disclosed that reduces dimensions (e.g., an X and Y dimension) of the electronic module by placing some or all of the passive components on a side of a PCB that is opposite a side in which an active component is placed on the PCB. In one embodiment, an active component is a component that relies on an external power source to control or modify electrical signals. Examples of an active component include an integrated circuit such an image sensor. In contrast, a passive component does not require an external power source control or modify electrical signals. Passive components merely require current travelling through the passive component to modify the electrical signals. Examples of passive components include a resistor, a diode, a capacitor, and an inductor. In order to reduce an increase in height (e.g., thickness) (Z dimension) of the electronic module due to placing the passive components and the active component on opposite sides of the PCB, the electronic module may further include local recesses in which the passive components are placed into.

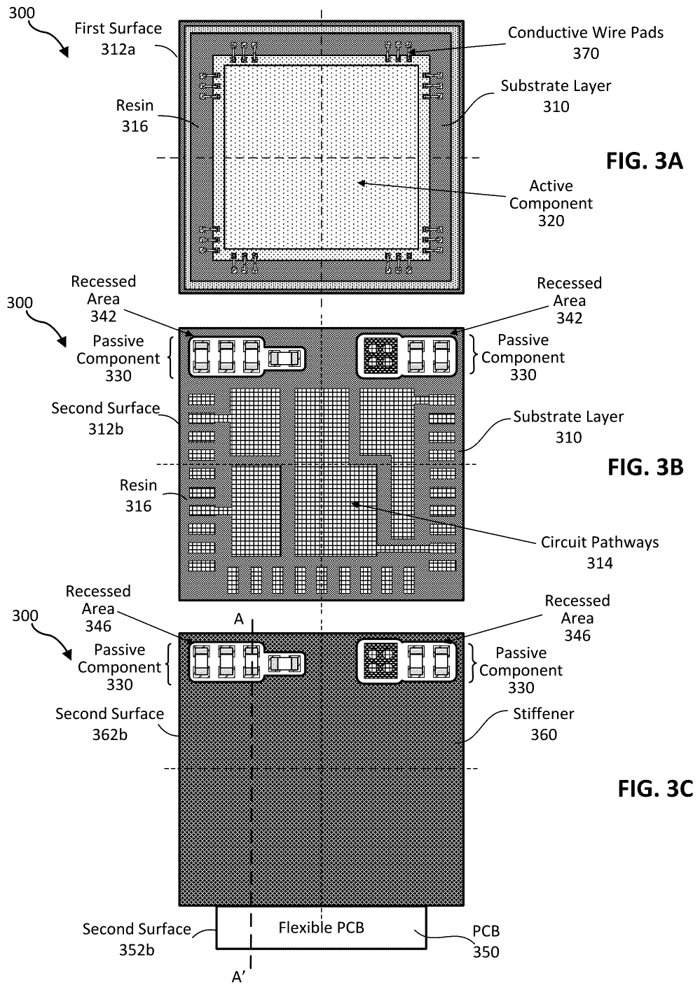

FIGS. 3A-3C illustrate exemplary surface views of an electronic module 300, in accordance with one or more embodiments. In particular, FIG. 3A illustrates a first side of the electronic module 300 and FIG. 3C illustrates a second side of the electronic module 300 according to one embodiment. FIG. 3B illustrates a back side of a substrate layer 310 included in the electronic module 300 according to one embodiment.

The electronic module 300 may be a PCB structure, including a PCB substrate. In some embodiments, the electronic module 300 may be a camera module. The electronic module 300 may be a component of the camera devices 115A, 115B, which are configured to capture data (e.g., one or more images) of a local area surrounding the electronic wearable device 100/200, for example.

FIG. 3A illustrates a first side (e.g., a top side) of the electronic module 300 according to one embodiment. As shown in FIG. 3A, the electronic module 300 includes a substrate layer 310 and an active component 320 (e.g., an image sensor) on the substrate layer 310. The active component 320 is mounted on a first surface 312a (e.g., a top surface) of the substrate layer 310. The active component 320 is electrically connected with the first surface 312a of the substrate layer 310 using a plurality of conductive wire pads 370. While only a single active component 320 is shown on the first side of the electronic module 300, multiple active components 320 may be placed on the first side of the electronic module 300.

FIG. 3B shows a second surface 312b (e.g., a back side) of a substrate layer 310 that is included in the electronic module 300. The second surface 312b is opposite to the first surface 312a. In one embodiment, the substrate layer 310 includes a plurality of recessed areas 342. In one embodiment, a recessed area 342 is a recess formed in the substrate layer 310 that extends partially through a thickness of the substrate layer 310 toward the first surface 312a without reaching the first surface 312a.

One or more electronic components 330 are placed (e.g., disposed or inserted) in the plurality of recessed areas 342. In one embodiment, a single electronic component 330 may be placed in a recessed area 342 or multiple components 330 may be placed in a single recessed area 342. The electronic components may be passive components, such as, resisters, capacitors, and inductors, etc.

The dimensions of the recessed areas 342 may be customized (e.g., designed) based on the dimensions of the electronic components 330 to be placed in the recessed areas 342. The recessed areas 342 may be filled with non-conductive adhesives so that the electronic components 330 are adhered (e.g., secured) to the recessed areas 342. The second surface 312b of the substrate layer 310 may also include patterned electrically conductive material that forms circuit pathways 314, and resin 316 that isolates the different circuit pathways 314 in the substrate layer 310.

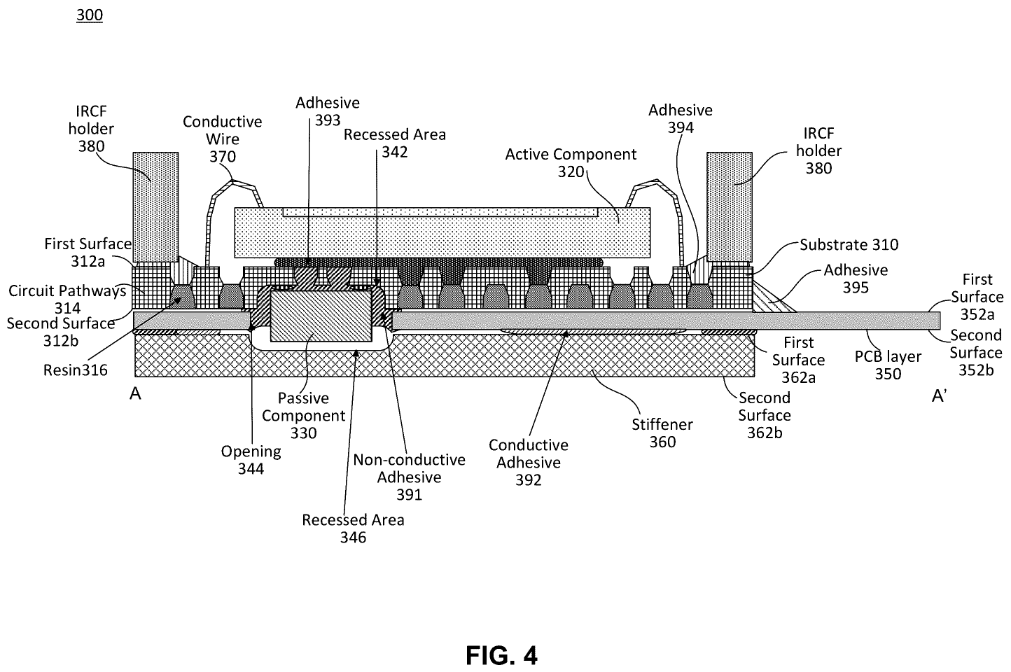

FIG. 3C illustrates a second side of the electronic module 300 according to one embodiment. In FIG. 3C, a flexible PCB layer 350 is mounted on the second surface 312b of the substrate layer 310, and a stiffener layer 360 is mounted on the flexible PCB layer 350. Thus, the flexible PCB layer 350 is disposed between the substrate layer 310 and the stiffener layer 360. As shown in FIG. 3C, the stiffener layer 360 is configured to at least partially cover a surface 352b of the flexible PCB layer 350. A surface 362b of the stiffener layer 360 may also include one or more recessed areas 346 that overlap with openings on the flexible PCB layer 350 (shown in FIG. 4). In this way, the recessed areas 342 on the second surface 312b of the substrate layer 310, the openings of the flexible PCB layer 350, and the opening areas 346 on the stiffener layer 360 are aligned and form a plurality of receptacles to accommodate the electronic components 330. In FIG. 3C, the recessed areas 346 of the stiffener layer 360 are visible for explanation purposes. As will be described with respect to FIG. 4, the recessed areas 346 of the stiffener layer 360 may or may not extend through the thickness of the stiffener layer 360 to make the recessed areas 346 visible from the second side of the electronic module 300 as shown in FIG. 3C.

FIG. 4 illustrates a cross sectional view of the electronic module 300 along line A-A′ of FIG. 3C, in accordance with one or more embodiments. The electronic module 300 may include the substrate layer 310, the active component 320, one or more passive components 330, the flexible PCB layer 350, and the stiffener layer 360 as previously described above. In some embodiment, the substrate layer 310 may be another PCB layer, and the electronic module 300 is a PCB structure. In alternative configurations, different and/or additional components may be included in the electronic module 300. However, it is not necessary that all of these components be shown in order to disclose an illustrative embodiment.

The substrate layer 310 includes the first surface 312a and the second surface 312b that is opposite to the second surface 312b. In one example, the first surface 312a of the substrate layer 310 may be a lens-facing surface, on which an image sensor (e.g., the active component 320) may be mounted. In one embodiment, an adhesive 393 is applied between the active component 320 and the first surface 312a of the substrate layer 310 to attach the active component 320 to the substrate layer 310. The adhesive 393 may be a glue, for example. The one or more passive components 330 are mounted on the second surface 312b of the substrate layer 310 rather than on the first surface 312a to reduce the dimensions of the electronic module 300.

The second surface 312b of the substrate layer 310 includes a recessed area 342 shown in FIG. 4. The recessed area 342 extends through a portion of the substrate layer 310 towards the first surface 312a of the substrate layer 310. The recessed area 342 may be sized to receive the one or more passive components 330 such that the passive components 330 are placed into the recessed area 342 on the second surface 312b. For example, the recessed area may extend through half of the thickness of the substrate layer 310 towards the first surface 312a of the substrate layer 310 based on the thickness of the passive components 330. In some other embodiments, some or all of the one or more passive components 330 of the electronic module 300 may be placed into the substrate layer 310 on the second surface 312b.

The electronic module 300 also includes electrical connections for the plurality of passive components 330 and the active component 320. The first surface 312a of the substrate layer 310 is electrically connected to the active component 320 by conductive wires (pads) 370. As shown in FIG. 4, a first end of a conductive wire 370 is connected to the active component 320 and a second end of the conductive wire 370 is connected to the first surface 312a of the substrate layer 310 to electrically connect the active component 320 to the substrate layer 310. In one embodiment, the passive components 330 are electrically connected to one or more circuit pathways 314 via soldering or a conductive epoxy within the recessed area 342.

The substrate layer 310 may include thermal conductive materials, e.g., copper material, which may have a high thermal conductivity that can be used to dissipate heat and mitigate temperature rise of the image sensor 320. As described above, the substrate layer 310 includes circuit pathways 314 made of electrically conductive material (e.g., copper or other conductive materials) that is patterned and filled with an insulator (e.g., resin) 316 as shown in FIG. 3 and FIG. 4. The resin 316 isolates different circuit pathways 314 from each other in the substrate layer 310. The circuit pathways 314 formed with the conductive material may be used to conduct signals between the active component 320, the passive components 330, and circuits external to the electronic module 300 such as a camera controller, for example.

The flexible PCB layer 350 provides circuit pathways between the active component 320 and other elements that are external to the electronic module 300 such as a camera controller, a Power Management Unit, plurality of components, etc. The flexible PCB layer 350 may also be electrically coupled to the one or more passive components 330 via circuit pathways 314 on the substrate layer 310.

The flexible PCB layer 350 may include a first surface 352a and second surface 352b that is opposite to the first surface 352a. The first surface 352a is coupled to the second surface 312b of the substrate layer 310. In one embodiment, an adhesive 395 adheres a portion of the first surface 352a of the flexible PCB layer 350 to a surface (e.g., a side surface) of the substrate layer 310 as shown in FIG. 4. The adhesive 395 reinforces the structure and increase the mechanical stability of the electronic module 300.

In some embodiments, the flexible PCB layer 350 may include one or more openings 344 (e.g., recesses) that overlaps with the recessed areas 342 on the second surface 312b of the substrate layer 310 so that one or more of the passive components 330 can fit through the openings 344. Thus, a portion of the passive components is disposed in the openings 344 of the flexible PCB layer 350. In one embodiment, the opening 344 of the flexible PCB layer 350 extends from the first surface 352a to the second surface 352b of the flexible PCB layer 350. Thus, the opening 344 is formed though the entire thickness of the flexible PCB layer 350. Similar to the recessed areas 342, the dimensions of the openings 344 are based on the dimensions of the passive components 330 placed in the recessed areas 342.

In one embodiment, a non-conductive adhesive 391 (e.g., non-conductive epoxy) is applied to the opening 344 of the flexible PCB layer 350 and the recessed areas 342. The non-conductive adhesive 391 fills in the space between the passive components 330 and the flexible PCB layer 350 and the substrate layer 310 in the opening 344 and the recessed areas 342. As shown in FIG. 4, the non-conductive adhesive 391 adheres the passive components 330 to at least one of the substrate layer 310 and the flexible PCB layer 350 to maintain the passive component 330 inside a receptacle formed via the opening 344 and the recessed area 342.

The stiffener layer 360 is configured to provide a rigid support structure of the electronic module 300. The stiffener layer 360 may be metal and may form a ground plane for the electronic module 300, for example. The stiffener layer 360 may include a first surface 362a and a second surface 362b that is opposite to the second surface 362b. As shown in FIG. 4, the first surface 362a of the stiffener layer 360 is coupled to the second surface 352b of the flexible PCB layer 350.

In one embodiment, a non-conductive adhesive 361 that is used to secure the passive component 330 to the substrate layer 310 and the flexible PCB layer 350 may also be applied between the periphery of the second surface 352b of the flexible PCB layer 350 and the first surface 362a of the stiffener layer 360 to adhere together the flexible PCB layer 350 and the stiffener layer 360. Additionally, a conductive adhesive 392 (e.g., conductive epoxy) may be applied between the second surface 352b of the flexible PCB layer 350 and the first surface 362a of the stiffener layer 360 on some local areas to increase the respective electric conductivity. The stiffener layer 360 is configured to at least partially cover the second surface 352b of the flexible PCB layer 350 as shown in FIG. 4 while the stiffener layer 360 and the flexible PCB layer 350 are attached to each other.

In some embodiments, the first surface 362a of the stiffener layer 360 may include one or more recesses 346 (e.g., openings) that overlap with the openings 344 on the second surface 352b of the flexible PCB layer 350 and the recessed areas 342 of the substrate layer 310. The recesses 346 on the first surface 362b of the stiffener layer 360 may be sized to accommodate the passive components that are placed in the recessed area 342 on the second surface 312b of the substrate layer 310.

As shown in FIG. 4, in one embodiment, the recesses 346 of the stiffener layer 360 extend from the first surface 362a partially through a thickness of the stiffener layer 360 toward the second surface 362b without reaching the second surface 362b. Thus, the recesses 346 are formed though a partial thickness of the stiffener layer 360. However, in another embodiment, the recesses 346 of the stiffener layer 360 extend from the first surface 362a through the entire thickness of the stiffener layer 360 to the second surface 362b.

The recessed areas 342 on the second surface 312b of the substrate layer 310, the openings 344 of the flexible PCB layer 350, and the recesses 346 on the first surface 362a of the stiffener layer 360 collectively form one or more receptacles for the passive components 330. The depths of the receptacles are larger than the heights or thicknesses (in Z dimension) of the passive components 330. In some examples, the depth of a recessed area 342 on the second surface 312b may range from 100 to 120 μm.

As shown in FIG. 4, by placing the passive component in the formed receptacle a height of the electronic module 300 is reduced in the Z dimension. Here, the z-direction is parallel to the optical axis of the electronic device 300. The electronic module 300 with a recessed substrate layer 310 provides substantial reductions in form factor. Placement of passive components 330 and the active component 320 on opposite sides of the recessed substrate layer 310 provide a reduction in X and Y dimensions, and embedding the plurality of passive components 330 in the recessed substrate layer 310 provides a reduction in form factor along the Z dimension.

In one embodiment, the electronic module 300 is a camera module for a camera device. In the camera example, the active component 320 is an image sensor that is configured to receive visible light and/or infrared light from the local area surrounding of a camera device. For a camera device integrated into an electronic device, e.g., wristband system 100, the local area is an area surrounding the electronic device. The visible and/or infrared light is focused from the local area to the image sensor 320 via a lens assembly. The image sensor 320 may include one or more individual sensors, e.g., a photodetector, a CMOS sensor, a CCD sensor, some other device for detecting light, or some combination thereof. The individual sensors may be in an array. The image sensor 320 may include various filters, such as IRCF (cut-filter). The IRCF is a filter configured to block the infrared light from the local area and propagate the visible light to the image sensor 320. The IRCF may be placed within the IRCF holder 380 that is adhered to the substrate layer 310 via an adhesive 394. The image sensor 320 is mounted on the first surface 312a of the substrate layer 310 and may be connected to a camera controller or CPU though the flexible PCB layer 350 or others by wire bonding, flip chip and other technologies.

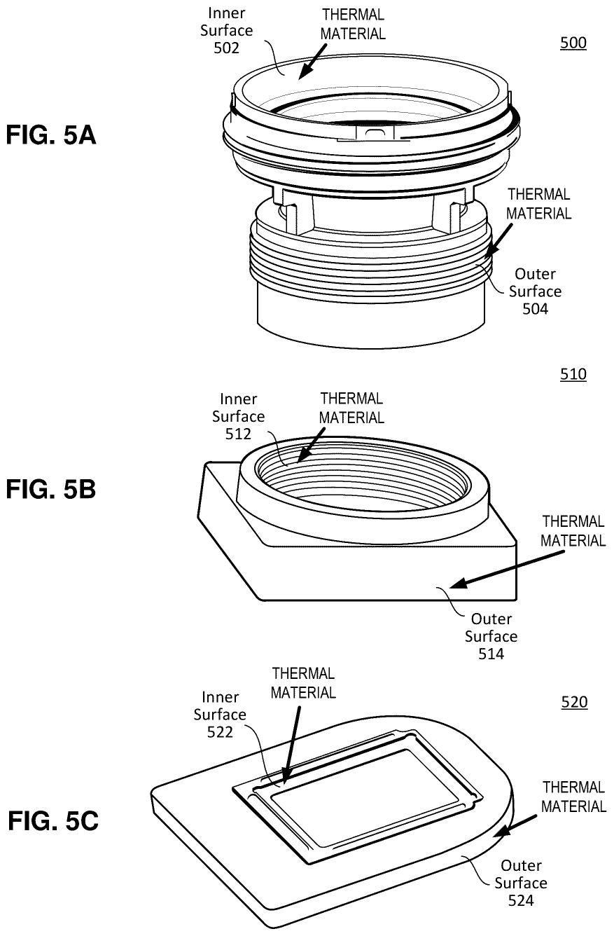

In one embodiment, the lens assembly for the camera example includes one or more optical elements, and a lens barrel 500 as shown in FIG. 5A. The lens barrel 500 functions to hold the one or more optical elements in optical series with each other. In some embodiments, each optical element may be held within the lens barrel 500 via a lens holder 510 as shown in FIG. 5B. The lens barrel 500 is a hollow structure with an opening on opposite ends of the lens barrel 500. The openings may provide a path for light (e.g., visible light, infrared light, etc.) to transmit between a local area and the image sensor 320. The lens barrel 500 may be manufactured from a wide variety of materials ranging from plastic to metals.

The components in a camera device may be affected by thermal changes caused by the ambient environment, the local environment, and the heat generated by active components (e.g., the image sensor) of the camera device. In conventional camera designs, thermal management efforts are normally focused on getting heat generated from the image sensor effectively dissipated to other thermally conductive components, i.e., metal thermal block which is attached the device enclosure with large surface area. Other ways include power reduction, or separation of other major heat sources, such as battery, and MLB (main logic board) away from the cameras. However, in a system with a small formfactor, these thermal management approaches may not be sufficient.

The electronic module 300 described herein has high thermal dissipation and isolation. The electronic module 300 include thermal features that facilitate heat dissipation and/or thermal isolation of heat sensitive components (e.g., lens assembly, lens holder, sensor base holders).

Some or all of the lens barrel 500, some or all of one or more lens holders 510, the IRFC holder 520 (also called sensor holder, shown in FIG. 5C), or some combination thereof may be coated with a thermal material to mitigate the temperature rise of the optical elements. In some embodiments, the thermal material includes a thermal conductive material that is coated on an inner surface 502 of the lens barrel 500, an inner surface 512 of the lens holder 510, an inner surface 522 of the IRFC holder 520, or some combination thereof, to increase the heat dissipation from the optical elements to the surrounding components. In some embodiments, the thermal material includes a thermal insulating material that is coated on an outer surface 504 of the lens barrel 500, an outer surface 514 of the lens holder 510, an outer surface 524 of the IRFC holder 520, or some combination thereof, to prevent or at least reduce heat conduction from neighboring heat generating components.

The thermal material may include a ceramic coating, such as an acrylic paint material mixed with ceramic particles or microspheres that mitigate heat crossing through. Depending on the ceramic particle concentration variation, ceramic coatings may be a very good thermal insulator, or can also be mixed with holes for heat dissipation. The thermal material may be applied via, e.g., spray coating, paint, customized taping film, and etc. Thickness of the applied thermal material can be adjusted and controlled with material composition engineering and coating process control.

In addition to thermal material coating, a water insulated stiffener layer can be attached to a backside of the flexible PCB layer 350 via conductive paste. A thin stamped copper plate film can be used to seal deionized (DI) water which offers much higher thermal capacity than the commonly used thin copper tape. In some embodiments, the stiffener layer 360 can be further attached to additional thermal blocks. Dimension of the water circulated stiffener layer can be customized and thickness can be controlled in the range of 100-300 μm. Alternatively, and/or in combination with active liquid cooling, the stiffener layer may be coated with one or more thermal materials to facilitate dissipation of heat generated by, e.g., the optical elements. In some of the embodiments, high thermal conductive material with electrical conductivity, or electrical non-conductivity can be applied to the back side of the PCB layer for both heat dissipation and grounding purposes.

### Additional Configuration Information

The foregoing description of the embodiments has been presented for illustration; it is not intended to be exhaustive or to limit the patent rights to the precise forms disclosed. Persons skilled in the relevant art can appreciate that many modifications and variations are possible considering the above disclosure.

Some portions of this description describe the embodiments in terms of algorithms and symbolic representations of operations on information. These algorithmic descriptions and representations are commonly used by those skilled in the data processing arts to convey the substance of their work effectively to others skilled in the art. These operations, while described functionally, computationally, or logically, are understood to be implemented by computer programs or equivalent electrical circuits, microcode, or the like. Furthermore, it has also proven convenient at times, to refer to these arrangements of operations as modules, without loss of generality. The described operations and their associated modules may be embodied in software, firmware, hardware, or any combinations thereof.

Any of the steps, operations, or processes described herein may be performed or implemented with one or more hardware or software modules, alone or in combination with other devices. In one embodiment, a software module is implemented with a computer program product comprising a computer-readable medium containing computer program code, which can be executed by a computer processor for performing any or all the steps, operations, or processes described.

Embodiments may also relate to an apparatus for performing the operations herein. This apparatus may be specially constructed for the required purposes, and/or it may comprise a general-purpose computing device selectively activated or reconfigured by a computer program stored in the computer. Such a computer program may be stored in a non-transitory, tangible computer readable storage medium, or any type of media suitable for storing electronic instructions, which may be coupled to a computer system bus. Furthermore, any computing systems referred to in the specification may include a single processor or may be architectures employing multiple processor designs for increased computing capability.

Embodiments may also relate to a product that is produced by a computing process described herein. Such a product may comprise information resulting from a computing process, where the information is stored on a non-transitory, tangible computer readable storage medium and may include any embodiment of a computer program product or other data combination described herein.

Finally, the language used in the specification has been principally selected for readability and instructional purposes, and it may not have been selected to delineate or circumscribe the patent rights. It is therefore intended that the scope of the patent rights be limited not by this detailed description, but rather by any claims that issue on an application based hereon. Accordingly, the disclosure of the embodiments is intended to be illustrative, but not limiting, of the scope of the patent rights, which is set forth in the following claims.

What is claimed is:

1. An electronic module, comprising:
a substrate including a first surface and a second surface that is opposite the first surface, the second surface of the substrate including a recessed area that extends through a portion of the substrate towards the first surface of the substrate;
an active component on the first surface of the substrate;
a passive component in the recessed area of the second surface of the substrate;
a printed circuit board (PCB) including an opening that extends from a first surface of the PCB to a second surface of the PCB; and
a stiffener having a recess extending from a first surface of the stiffener toward a second surface of the stiffener,
wherein the recess of the stiffener overlaps the opening of the PCB and overlaps the recessed area of the substrate,
and wherein the passive component is disposed in the recessed area of the substrate, the opening of the PCB, and the recess of the stiffener.

2. The electronic module of claim 1, wherein the active component is an image sensor configured to capture an image and the passive component is one of a resistor, a capacitor, and an inductor.

3. The electronic module of claim 1, wherein the substrate includes an insulator and a plurality of conductive pathways, the active component on the first surface of the substrate electrically connected to the passive component in the recessed area of the second surface via one or more of the plurality of conductive pathways.

4. The electronic module of claim 3, wherein the insulator comprises resin that electrically insulates at least two conductive pathways from the plurality of pathways from each other.

5. (canceled)

6. The electronic module of claim 1, further comprising:
an adhesive that adheres the passive component to at least one of the substrate and the PCB.

7. (canceled)

8. The electronic module of claim 1, wherein a depth of the recessed area, the opening of the PCB, and the recess of the stiffener while overlapping is greater than a thickness of the passive component.

9. The electronic module of claim 1, wherein the active component is an image sensor configured to capture an image, the electronic module further comprising:
a lens assembly coupled to the image sensor, the lens assembly configured to focus light from a local area to the image sensor of the electronic module, the lens assembly including:
a lens;
a lens barrel and a lens holder configured to hold the lens; and
a thermal material coated on at least a portion of the lens barrel and the lens holder.

10. The electronic module of claim 9, further comprising:
an IRCF holder coated with the thermal material.

11. The electronic module of claim 10, wherein the thermal material includes a thermal insulating material coated on outer surfaces of the lens barrel, lens holder, and the IRCF holder, the thermal insulating material configured to at least reduce heat conduction.

12. The electronic module of claim 10, wherein the thermal material includes a thermal conductive material coated on inner surfaces of the lens barrel, lens holder, and the IRCF holder, the thermal material configured to increase heat dissipation.

13. A wearable device comprising:
an electronic module including:
a substrate including a first surface and a second surface that is opposite the first surface, the second surface of the substrate including a recessed area that extends through a portion of the substrate towards the first surface of the substrate;
an active component on the first surface of the substrate;
a passive component in the recessed area of the second surface of the substrate;
a printed circuit board (PCB) including an opening that extends from a first surface of the PCB to a second surface of the PCB; and
a stiffener having a recess extending from a first surface of the stiffener toward a second surface of the stiffener, wherein the recess of the stiffener overlaps the opening of the PCB and overlaps the recessed area of the substrate, and wherein the passive component is disposed in the recessed area of the substrate, the opening of the PCB, and the recess of the stiffener.

14. The device of claim 13, wherein the active component is an image sensor configured to capture an image and the passive component is one of a resistor, a capacitor, and an inductor.

15. The device of claim 13, wherein the substrate includes an insulator and a plurality of conductive pathways, the active component on the first surface of the substrate electrically connected to the passive component in the recessed area of the second surface via one or more of the plurality of conductive pathways.

16. (canceled)

17. (canceled)

18. The device of claim 13, wherein the active component is an image sensor configured to capture an image, the electronic module further comprising:
a lens assembly coupled to the image sensor, the lens assembly configured to focus light from a local area to the image sensor of the electronic module, the lens assembly including:
a lens;
a lens barrel and a lens holder configured to hold the lens;
an IRCF holder, and
a thermal material coated on at least a portion of the lens barrel, the lens holder and the IRCF holder.

19. The device of claim 18, wherein the thermal material includes a thermal insulating material coated on outer surfaces of the lens barrel, the lens holder and the IRCF holder, the thermal insulating material configured to at least reduce heat conduction.

20. The device of claim 18, wherein the thermal material includes a thermal conductive material coated on inner surfaces of the lens barrel, the lens holder and the IRCF holder, the thermal material configured to increase heat dissipation.

21. The electronic module of claim 1, wherein the thermal material includes a ceramic coating.

22. The electronic module of claim 1, wherein the stiffener includes a water insulated stiffener layer including:
deionized water; and
a thin stamped copper plate film sealing the deionized water.

23. A camera module comprising:
a substrate including a first surface and a second surface that is opposite the first surface, the second surface of the substrate including a recessed area that extends through a portion of the substrate towards the first surface of the substrate;
an image sensor disposed on a first surface of the substrate;
a printed circuit board (PCB) having an opening that extends from a first surface of the PCB to a second surface of the PCB that is opposite the first surface of the PCB;
a stiffener including a recess that extends from a first surface of the stiffener toward a second surface of the stiffener that is opposite a first surface of the stiffener; and
a passive component conductively coupled to the image sensor, wherein the passive component is adhered to the recessed area of the substrate and adhered to the opening of the PCB, and wherein the passive component is in: (1) the recessed area of the substrate; (2) the opening in the PCB; and (3) the recess of the stiffener that overlaps the opening of the PCB and overlaps the recessed area of the substrate.

24. The camera module of claim 23, wherein the stiffener is a metal stiffener adhered to the PCB with conductive adhesive to provide a rigid support structure to the camera module, the recess of the stiffener being in a metal of the metal stiffener.
